(19) United States
(12) Patent Application Publication
(10) Pub. No.: US 2023/0138079 A1
(43) Pub. Date: May 4, 2023

(54) LITHOGRAPHY SYSTEM

(71) Applicant: CHANGXIN MEMORY TECHNOLOGIES, INC., Hefei City (CN)

(72) Inventor: MEI-LI WANG, Hefei (CN)

(21) Appl. No.: 17/854,207

(22) Filed: Jun. 30, 2022

Related U.S. Application Data
(63) Continuation of application No. PCT/CN2021/138261, filed on Dec. 15, 2021.

(30) Foreign Application Priority Data
Nov. 3, 2021 (CN) 202111294253.0

(51) Int. Cl. G03F 1/40; G03F 1/42; H01L 21/027

(52) U.S. Cl. CPC G03F 1/40; G03F 1/42; H01L 21/0274

(57) ABSTRACT

A lithography system includes: a lithography device; and a mask adapted to the lithography device and having an exposed area and a non-exposed area surrounding the exposed area. The mask includes: a device pattern, arranged in the exposed area and configured to be projected onto photoresist covering a semiconductor structure during exposure; and an Electrostatic Discharge (ESD) ring, arranged in the exposed area and surrounding the device pattern. The ESD ring has a feature size less than a resolution of the lithography device. There is a preset spacing between the ESD ring and the device pattern.

### CROSS REFERENCE TO RELATED APPLICATIONS

This is a continuation application of International Patent Application No. PCT/CN2021/138261, filed on Dec. 15, 2021, which claims priority to Chinese Patent Application No. 202111294253.0, filed on Nov. 03, 2021 and entitled “LITHOGRAPHY SYSTEM”. The disclosures of International Patent Application No. PCT/CN2021/138261 and Chinese Patent Application No. 202111294253.0 are hereby incorporated by reference in their entireties.

### BACKGROUND

A mask is a graphic master mask used in lithography process, for transferring a design layout onto a semiconductor structure to form a semiconductor device. Therefore, the quality of the mask directly influences the quality of the semiconductor structure prepared, and then influences the yield of formed semiconductor devices including the semiconductor structure. Generally, the mask includes an exposed area and a non-exposed area. Moreover, in order to achieve alignment with an exposure machine, the mask is also provided with an alignment mark for alignment with the exposure machine. In addition, to reduce the influence of electrostatic discharge on the exposed area, an Electrostatic Discharge (ESD) ring is usually set. How to set the position of the ESD ring reasonably has become an urgent problem to be solved.

### SUMMARY

Embodiments of the present disclosure relate to the field of semiconductor device manufacturing, in particular to a lithography system. The lithography system may include a lithography device and a mask adapted to the lithography device.

The mask has an exposed area and a non-exposed area arranged around the exposed area. The mask includes a device pattern and an ESD ring.

The device pattern is arranged in the exposed area and configured to be projected onto photoresist covering a semiconductor structure during exposure.

The ESD ring is arranged in the exposed area and surrounds the device pattern. The ESD ring has a feature size less than a resolution of the lithography device. There is a preset spacing between the ESD ring and the device pattern.

### BRIEF DESCRIPTION OF THE DRAWINGS

FIG. 1A illustrates a schematic diagram of an exposed area of a mask according to an exemplary embodiment.

FIG. 1B illustrates a schematic diagram of a non-exposed area of a mask according to an exemplary embodiment.

FIG. 1C illustrates a schematic diagram of a mask according to an exemplary embodiment.

FIG. 1D illustrates a partial schematic diagram of a mask according to an exemplary embodiment.

FIG. 2A illustrates a block diagram of a lithography system according to an exemplary embodiment.

FIG. 2B illustrates a schematic diagram of an exposed area I of a mask according to an exemplary embodiment.

FIG. 2C illustrates a schematic diagram of a non-exposed area II of a mask according to an exemplary embodiment.

FIG. 2D illustrates a schematic diagram of a mask according to an exemplary embodiment.

FIG. 3A illustrates a schematic diagram of an exposed area I of another mask according to an exemplary embodiment.

FIG. 3B illustrates a schematic diagram of another mask according to an exemplary embodiment.

### DETAILED DESCRIPTION

The technical solutions of the present disclosure will further be elaborated below in combination with the drawings and the embodiments. Although the exemplary implementation modes of the disclosure are shown in the drawings, it should be understood that the disclosure may be implemented in various forms and shall not be limited by the implementation modes described here. Rather, these implementation modes are provided in order to have a more thorough understanding of the disclosure and to be able to fully convey the scope of the disclosure to those skilled in the art.

The present disclosure is more specifically described below by means of examples with reference to drawings. The advantages and features of the present disclosure will be clearer according to the following description and claims. It is to be noted that the accompanying drawings are all in a very simplified form with imprecise scale, to assist in illustrating the purpose of the embodiments of the present disclosure easily and clearly.

It is understandable that the meaning of “on”, “over” and “above” in the present disclosure should be interpreted in the broadest way, so that “on” means not only that an object is “on” something, without intermediate features or layers (that is, the object is directly on something), but also that an object is “on” something, with intermediate features or layers.

Terms “first”, “second”, “third” and the like in the embodiments of the present disclosure are adopted to distinguish similar objects and not intended to describe a specific sequence or order.

In the embodiments of the present disclosure, a term “layer” refers to a material part that includes an area with thickness. The layer may extend over the whole of a lower or upper structure, or may have a scope smaller than the scope of the lower or upper structure. Moreover, the layer may be an area of a homogeneous or heterogeneous continuous structure whose thickness is less than a thickness of a continuous structure. For example, the layer may be between the top surface and the bottom surface of the continuous structure, or the layer may be between any pair of horizontal surfaces at the top surface and bottom surface of the continuous structure. The layer may extend horizontally, vertically and/or along an inclined surface. The layer may include multiple sub-layers.

It is to be noted that the technical solutions recorded in the embodiments of the present disclosure may be freely combined without conflicts.

In the preparation process of a semiconductor device, it is usually necessary to form a structure with a specific pattern. For example, in the preparation process of a Dynamic Random Access Memory (DRAM), it is necessary to form on a wafer a capacitor hole which runs through a stack structure including a sacrificial layer and a support layer which are stacked, or to form in a preset structure multiple word line trenches or bit line trenches arranged in parallel. In order to form these specific patterns, exposure is implemented and the patterns are transferred by a mask to the photoresist covering the stack structure, or to the photoresist covering the preset structure, to form patterned photoresist. Then the patterned photoresist is taken as an etching mask layer to form the capacitor hole, the word line trench or the bit line trench by lithography.

In the conventional art, there is a problem of low yield of semiconductor devices formed after exposure and lithography. It is found by analysis and research that the reason for the low yield may be that electrostatic discharge may occur in the mask during exposure, which influences the imaging of the device pattern in the exposed area and thus reduces the consistency between the pattern projected onto the photoresist and the device pattern in the mask. For example, the pattern actually projected onto the photoresist and the device pattern in the mask may change in the shape, which results in short circuit or open circuit of the formed semiconductor device, and thus reduces the yield of the semiconductor devices.

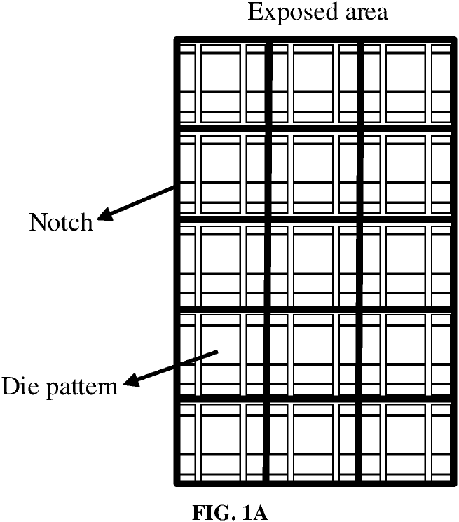

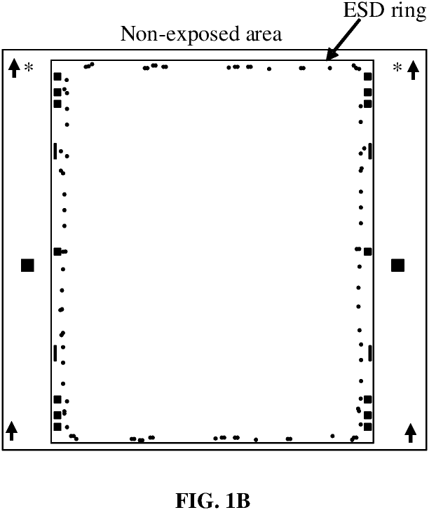

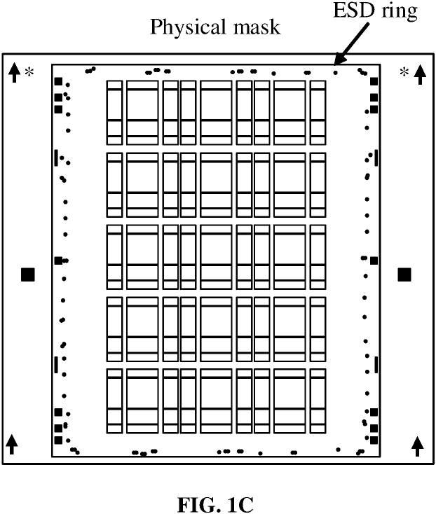

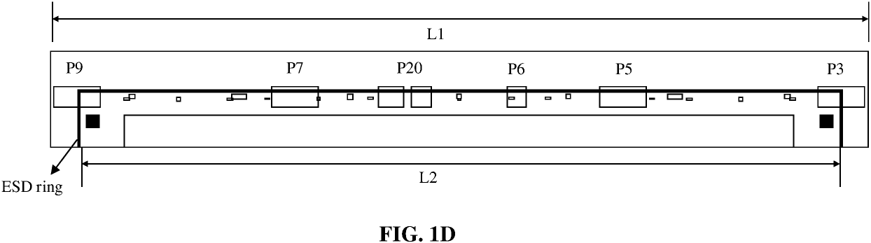

In order to solve the problem of the influence of the electrostatic discharge on the device pattern and protect the device pattern in the exposed area, an ESD ring may be arranged around the device pattern at the periphery of the device pattern. FIG. 1A illustrates a schematic diagram of an exposed area of a mask according to an exemplary embodiment. FIG. 1B illustrates a schematic diagram of a substrate including a non-exposed area according to an exemplary embodiment. FIG. 1C illustrates a schematic diagram of a mask (namely a physical photomask) including the exposed area illustrated in FIG. 1A and the non-exposed area illustrated in FIG. 1B. FIG. 1D illustrates a partial schematic diagram of the mask illustrated in FIG. 1C. It is understandable that the mask illustrated in FIG. 1C may be formed by combining the exposed area illustrated in FIG. 1A with the substrate including the non-exposed area illustrated in FIG. 1B.

As illustrated in FIG. 1A to FIG. 1D, the mask may usually include an exposed area and a non-exposed area. The exposed area is usually arranged at the center of the substrate of the mask. The non-exposed area is usually arranged on the edge of the substrate and around the exposed area. There is a device pattern arranged in the exposed area, and the device pattern is used for being projected onto the photoresist covering the semiconductor structure during exposure. The device pattern may include die patterns arranged in a matrix, and each core pattern corresponds to a die. An alignment mark (e.g. a dot, block or bar-shaped pattern illustrated in FIG. 1B) may be arranged in the non-exposed area for alignment of an exposure machine. As illustrated in FIG. 1D, the width L1 of the mask may be 126 mm, and the width L2 of the ESD ring may be 118 mm.

However, in practical application, if the ESD ring is arranged in the non-exposed area (as illustrated in FIG. 1B), the ESD ring will overlap the alignment marks used for alignment of the lithography machine, which cannot meet the requirement of the exposure machine for no other patterns presented in the area where the alignment mark is arranged on the mask. Taking the lithography machine ASML NXT1470 as an example, as illustrated in FIG. 1D, the lithography machine requires that no other patterns except the alignment mark are arranged in the areas P3, P5, P6, P7, P9 and P20.

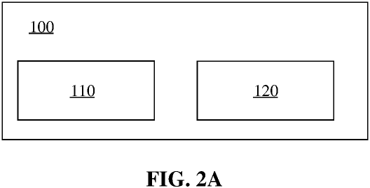

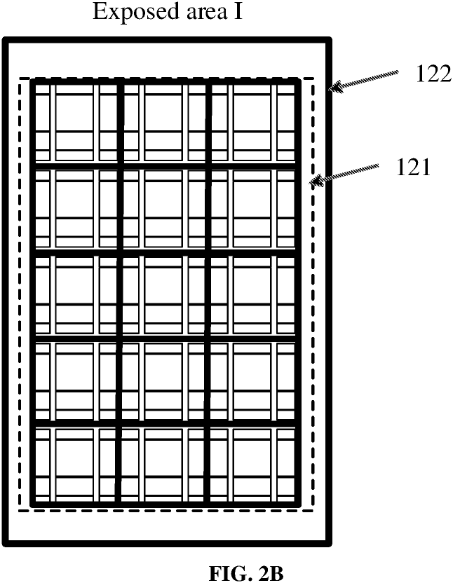

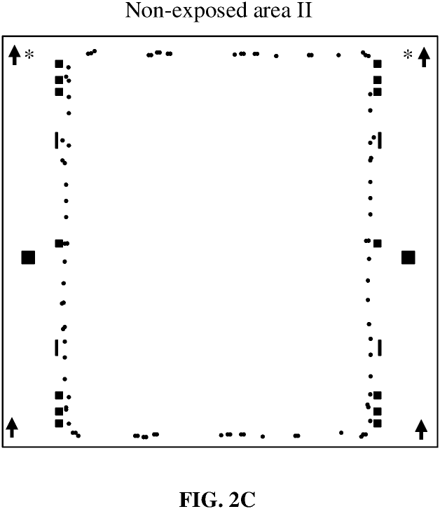

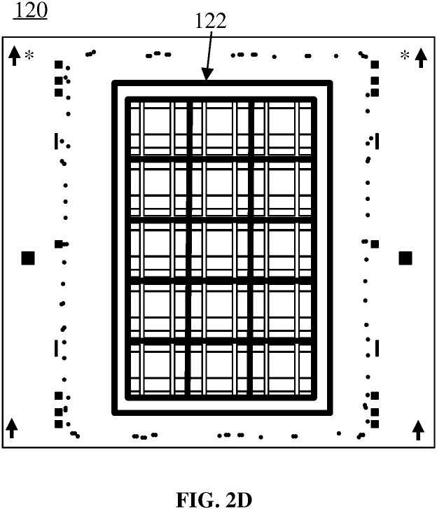

In view of this, the embodiments of the present disclosure provide a lithography system 100. As illustrated in FIG. 2A to FIG. 2D, the lithography system 100 may include a lithography device 110 and a mask 120 adapted to the lithography device 110.

The mask 120 has an exposed area I and a non-exposed area II arranged around the exposed area I. The mask 120 may include a device pattern 121 and an ESD ring 122.

The device pattern 121 is arranged in the exposed area I and configured to be projected onto a photoresist covering a semiconductor structure during exposure.

The ESD ring 122 is arranged in the exposed area I and surrounds the device pattern 121. The ESD ring 122 has a feature size less than the resolution of the lithography device 110. There is a preset spacing between the ESD ring 122 and the device pattern 121. The feature size includes or refers to a line width. Herein, the width of the ESD ring 122 is less than the exposure resolution, which can prevent the ESD ring 122 from being exposed.

The resolution of the lithography device 110 is used for indicating the ability of the lithography device 110 to clearly project the smallest image. The resolution R of the lithography device 110 may be calculated according to Rayleigh’s equation

$$R = {\text{K}}_{1} \times \frac{\text{λ}}{{N}_{A}}$$

, where K₁ represents a process related parameter, λ represents the wavelength of a light source used by the lithography device 110, and N_{A} represents a numerical aperture.

It is understandable that those skilled in the art may reasonably set the feature size of the ESD ring 122 in the mask 120 for different lithography devices 110, so as to meet the actual requirements of different processes, which is not limited in the present disclosure.

The feature size of the device pattern 121 is greater than or equal to the resolution of the lithography device 110. It is understandable that, in the embodiments of the present disclosure, by setting the feature size of the device pattern 121 to be greater than or equal to the resolution of the lithography device 110, it can be ensured that the device pattern 121 can be projected onto the photoresist covering the semiconductor structure to form a related functional structure.

Exemplarily, the device pattern 121 may be light-transmissive or opaque.

Specifically, when the device pattern 121 is light-transmissive, the device pattern 121 may include a first gap that runs through upper and lower surfaces of the mask 120. The photoresist covering the semiconductor structure is positive photoresist, an exposure light source reacts with the positive photoresist covering the semiconductor structure through the first gap. By baking and developing the positive photoresist, the device pattern 121 may be transferred to the photoresist to form a patterned photoresist layer.

When the device pattern 121 is light-transmissive, the device pattern 121 may also include a solid light-transmissive structure that runs through upper and lower surfaces of the mask 120. The photoresist covering the semiconductor structure is positive photoresist, the exposure light source reacts with the positive photoresist covering the semiconductor structure through the solid light-transmissive structure. By baking and developing the positive photoresist, the device pattern 121 may be transferred to the photoresist to form a patterned photoresist layer.

When the device pattern 121 is opaque, the device pattern 121 may be an opaque solid structure, and the area outside the device pattern 121 in the exposed area I is a second gap that runs through the upper and lower surfaces of the mask 120. The photoresist covering the semiconductor structure is negative photoresist, the exposure light source reacts with the negative photoresist covering the semiconductor structure through the second gap. By baking and developing the negative photoresist, the device pattern 121 may be transferred to the photoresist to form a patterned photoresist layer.

Exemplarily, the device pattern 121 may include a capacitor hole pattern for forming the capacitor hole in the semiconductor structure. The capacitor hole pattern includes, but is not limited to, circular or rectangular.

In some embodiments, the device pattern 121 may also include any or a combination of a contact plug pattern and a conductive wire pattern, which is not limited in the present disclosure.

Exemplarily, the ESD ring 122 is a closed pattern in shape, and the device pattern 121 is located inside the closed pattern of the ESD ring 122. Features of the ESD ring 122 may include the line width of the ESD ring 122. It needs to be emphasized that the device pattern 121 is not in contact with the ESD ring 122, that is, the preset spacing between the ESD ring 122 and the device pattern 121 is greater than 0.

It is understandable that although the ESD ring 122 is arranged in the exposed area I, the ESD ring 122 does not image in the photoresist covering the semiconductor structure during exposure through the lithography device 110 because the feature size of the ESD ring 122 is less than the resolution of the lithography device 110, that is, when the photoresist covering the semiconductor structure is exposed by the lithography system, the image formed in the photoresist is determined by the device pattern 121 in the exposed area I and will not be influenced by the ESD ring 122, and thus the formed device will not be influenced.

Exemplarily, types of the mask 120 include, but are not limited to, a Phase Shift Mask (PSM), a chromium mask (COG), or a molybdenum mask (OMOG). Preferably, a chrome less mask 120 may be used to reduce the influence on the device pattern 121.

Compared to the related art in which the position where the ESD ring 122 on the mask 120 is arranged overlaps the position where the alignment mark for alignment with the exposure machine is arranged, or the ESD ring 122 is removed from the mask 120, in the embodiments of the present disclosure, the ESD ring 122 is arranged in the exposed area I, and the feature size of the arranged ESD ring 122 is less than the resolution of the lithography device 110. In this way, not only the requirement of the exposure machine for no other patterns presented in the area where the alignment mark is arranged can be met, so as to reduce a loading effect of the pattern, but also the ESD ring 122 does not image when the lithography device 110 exposes, that is, forming of the device pattern 121 projected onto the photoresist covering the semiconductor structure will not be influenced, and the electrostatic protection of the device pattern 121 in the exposed area I can be achieved.

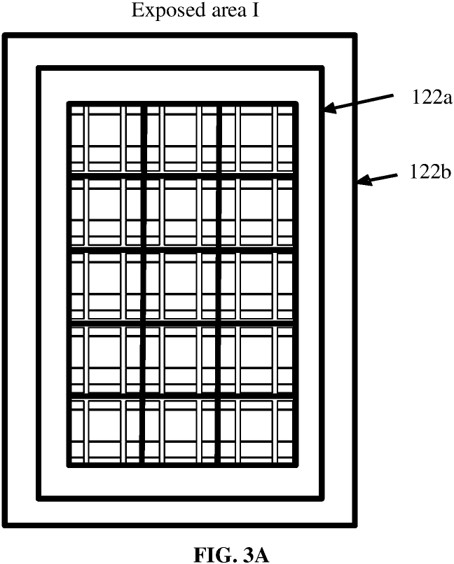

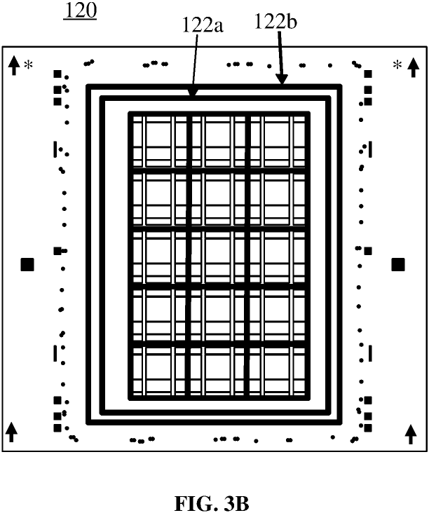

In some embodiments, as illustrated in FIG. 3A and FIG. 3B, the mask 120 includes multiple ESD rings arranged in parallel and surrounding the device pattern 121. The minimum distance between adjacent two ESD rings is greater than or equal to the feature size of the ESD ring.

It is understandable that each of the multiple ESD rings 122 arranged in parallel surrounds the device pattern 121, and each ESD ring 122 is a closed structure, so the multiple ESD rings 122 arranged in parallel are nested in each other.

As illustrated in FIG. 3A, the exposed area I of the mask 120 may include two ESD rings arranged in parallel and surrounding the device pattern 121, i.e., a first ESD ring 122a and a second ESD ring 122b respectively. The first ESD ring 122a is located between the second ESD ring 122b and the device pattern 121.

Exemplarily, the minimum distance between adjacent two ESD rings 122 may be represented by the minimum distance between any point on one of the ESD rings 122 and any point on the other one of the ESD rings 122.

When adjacent two ESD rings 122 are both annular, the minimum distance between the adjacent two ESD rings 122 may be represented by the difference between radii of the adjacent two ESD rings 122.

When adjacent two ESD rings 122 are both rectangular, the minimum distance between the adjacent two ESD rings 122 may be represented by half of the difference between diagonals of the adjacent two ESD rings 122.

Because the mask 120 includes multiple ESD rings 122, when at least two ESD rings 122 have different feature sizes, the minimum distance between adjacent two ESD rings 122 may be greater than or equal to the maximum value in the feature sizes of the multiple ESD rings 122.

Compared to arranging only one ESD ring 122, the mask 120 provided in the embodiments of the present disclosure may provide better electrostatic discharge capability by arranging multiple ESD rings 122 arranged in parallel and surrounding the device pattern 121. Especially when a single ESD ring 122 is not sufficient to resist the influence of electrostatic discharge on the device pattern 121, other ESD rings 122 may further protect the device pattern 121.

In some embodiments, the minimum distance between adjacent two ESD rings 122 is equal to 1.5 to 2.5 times the feature size of the ESD ring 122.

Exemplarily, when the feature sizes of adjacent two ESD rings 122 are the same, the minimum distance between the adjacent two ESD rings 122 may be equal to 1.5 to 2.5 times the feature size of any ESD ring 122, for example, 2 times the feature size of any ESD ring 122.

When the feature sizes of adjacent two ESD rings 122 are different, for example, when the first ESD ring and the second ESD ring are arranged adjacent to each other, and the feature size of the first ESD ring is less than that of the second ESD ring, the minimum distance between the first ESD ring and the second ESD ring may be equal to 1.5 to 2.5 times the feature size of the first ESD ring or 1.5 to 2.5 times the feature size of the second ESD ring.

In the embodiments of the present disclosure, by setting the minimum distance between adjacent two ESD rings 122 to be equal to 1.5 to 2.5 times the feature size of the ESD ring 122, on the one hand, the probability of imaging in the photoresist because of forming a dense pattern by multiple ESD rings 122 due to a too small distance between adjacent ESD rings 122 may be reduced, which can meet the requirement on that the ESD ring 122 will not influence the pattern projected onto the photoresist, and ensure that the formed semiconductor device meets the requirement on the yield; on the other hand, compared to setting the minimum distance between adjacent ESD rings 122 too large, the embodiments of the present disclosure may reduce the area of the exposed area I occupied by the ESD rings 122.

In some embodiments, multiple ESD rings 122 are equally spaced apart.

Specifically, the spacing between any two adjacent ESD rings 122 is equal. It needs to be emphasized that the spacing between any two adjacent ESD rings 122 is equal to 1.5 to 2.5 times the feature size of the ESD ring 122.

Compared to that there are at least two different spacings among multiple ESD rings 122, the layout of the ESD rings 122 is advantageously optimized by setting multiple ESD rings 122 equally spaced apart in the embodiments of the present disclosure,.

In some embodiments, multiple ESD rings 122 have a same width.

The width of the ESD ring 122 may be represented by the line width of the ESD ring 122. Taking that the ESD ring 122 is annular as an example, the annular ESD ring 122 includes an inner annular surface and an outer annular surface arranged opposite to the inner annular surface, and the line width of the annular ESD ring 122 is the spacing between the inner annular surface and the outer annular surface.

Compare to setting at least two ESD rings 122 with different widths, multiple ESD rings 122 in the embodiments of the present disclosure have the same width, which helps to reduce the difficulty of forming the mask 120 including the multiple ESD rings 122.

In some embodiments, the centers of symmetry of multiple ESD rings 122 overlap with each other.

Exemplarily, each ESD ring 122 may be a symmetric pattern.

It is understandable that when the centers of symmetry of at least two ESD rings 122 change from an overlapping state to a non-overlapping state, and at least two ESD rings 122 are arranged on the mask 120, an overlapping area surrounded by the at least two ESD rings 122 will decrease, and a non-overlapping area will increase, that is, the area required to arrange the at least two ESD rings 122 will increase.

Compared to setting at least two ESD rings 122 with their centers of symmetry not overlapped, by setting multiple ESD rings 122 with their centers of symmetry overlapped in the embodiments of the present disclosure, the layout of the multiple ESD rings 122 may be optimized to make full use of the area of the exposed area I. On the one hand, the area occupied by the ESD rings 122 may be reduced when the number of ESD rings 122 is unchanged; on the other hand, when the area of the exposed area I remains unchanged, the number of ESD rings 122 that can be set may be increased, which helps to improve the electrostatic protection effect of the device pattern 121.

In some embodiments, the shape of the ESD ring 122 may be a regular closed pattern; for example, the ESD ring 122 may have a rectangular, square or annular shape. It is understandable that the ESD ring 122 may also have a triangular or trapezoidal shape.

It is understandable that an irregular closed pattern usually has many inflection points, so it is difficult to form the mask 120 including the ESD ring 122 in the irregular closed pattern. Compared to taking the irregular closed pattern as the ESD ring 122, the shape of the ESD ring 122 provided in the embodiments of the present disclosure is the regular closed pattern, which reduces the difficulty of forming the mask 120 including the ESD ring 122 and can optimize the layout of the mask 120.

In some embodiments, materials for making the ESD ring 122 include quartz.

Exemplarily, the materials for making the ESD ring 122 may also include molybdenum or chromium. Preferably, a material not including chromium may be selected to form the ESD ring 122, so as to reduce the influence of chromium on the device pattern 121.

In some embodiments, the mask 120 may also include an alignment mark.

The alignment mark is arranged in the non-exposed area II and is configured to align the mask 120 with the light source of the lithography device 110.

In the process of exposing a wafer by the lithography device 110, the lithography device 110 may achieve the alignment of the mask 120 with the wafer through the alignment mark, so as to ensure that the device pattern 121 on the mask 120 can be projected onto a preset position in the photoresist covering the wafer.

In some embodiments, the lithography device 110 includes: the I-Line lithography machine, the KrF lithography machine, the ArF dry lithography machine or ArF immersion lithography machine.

Exemplarily, the lithography devices 110 may be distinguished according to the different light sources used by the lithography devices 110. For example, when the light source is mercury light, the lithography device 110 is the I-line lithography machine. When the light source is krypton fluoride, the lithography device 110 is the KrF lithography machine. When the light source is argon fluoride, the lithography device 110 is the ArF dry lithography machine or ArF immersion lithography machine.

For the lithography system provided by the embodiments of the present disclosure, the mask 120 may be flexibly designed or selected according to the lithography device 110 used, thereby meeting the application requirement and expanding the application range of the lithography system.

In some embodiments, the lithography device 110 is the I-Line lithography machine, and the feature size of the ESD ring 122 is less than 1120 nm.

It needs to be emphasized that according to the Rayleigh’s equation, the resolution of the lithography device 110 is positively correlated with the wavelength of the light source used by the lithography device 110 when other parameters are constant, and thus as the light source used by the lithography device 110 varies, the resolution of the lithography device 110 varies, and the feature size of the ESD ring 122 in the corresponding mask 120 also varies.

When the lithography device 110 is the I-Line lithography machine, and the wavelength of the light source is 365 nm, the resolution of the I-Line lithography machine that can be calculated according to the Rayleigh’s equation is 1120 nm, that is, when the lithography device 110 is used to expose the photoresist through the mask 120, the minimum feature size of the pattern to be imaged on the mask 120 is 1120 nm, therefore, the feature size of the ESD ring 122 is less than 1120 nm.

When the lithography device 110 is the I-Line lithography machine, and the wavelength of the light source is 365 nm, the smallest feature size of the pattern that can be formed on the wafer may be 280 nm.

In some embodiments, the lithography device 110 is the KrF lithography machine, and the feature size of the ESD ring 122 is less than 320 nm.

When the lithography device 110 is the KrF lithography machine, and the wavelength of the light source is 248 nm, the resolution of the KrF lithography machine that can be calculated according to the Rayleigh’s equation is 320 nm, that is, when the lithography device 110 is used to expose the photoresist through the mask 120, the minimum feature size of the pattern to be imaged on the mask 120 is 320 nm, therefore, the feature size of the ESD ring 122 is less than 320 nm.

When the lithography device 110 is the KrF lithography machine, and the wavelength of the light source is 248 nm, the smallest feature size of the pattern that can be formed on the wafer may be 80 nm.

In some embodiments, the lithography device 110 is the ArF dry lithography machine, and the feature size of the ESD ring 122 is less than 228 nm.

When the lithography device 110 is the ArF dry lithography machine, and the wavelength of the light source is 193 nm, the resolution of the ArF dry lithography machine that can be calculated according to the Rayleigh’s equation is 228 nm, that is, when the lithography device 110 is used to expose the photoresist through the mask 120, the minimum feature size of the pattern to be imaged on the mask 120 is 228 nm, therefore, the feature size of the ESD ring 122 is less than 228 nm.

When the lithography device 110 is the ArF dry lithography machine, and the wavelength of the light source is 193 nm, the smallest feature size of the pattern that can be formed on the wafer may be 57 nm.

In some embodiments, the lithography device 110 is the ArF immersion lithography machine, and the feature size of the ESD ring 122 is less than 152 nm.

When the lithography device 110 is the ArF immersion lithography machine, and the wavelength of the light source is 193 nm, the resolution of the ArF immersion lithography machine that can be calculated according to the Rayleigh’s equation is 152 nm, that is, when the lithography device 110 is used to expose the photoresist through the mask 120, the minimum feature size of the pattern to be imaged on the mask 120 is 152 nm, therefore, the feature size of the ESD ring 122 is less than 152 nm.

When the lithography device 110 is the ArF immersion lithography machine, and the wavelength of the light source is 193 nm, the smallest feature size of the pattern that can be formed on the wafer may be 38 nm.

It is understandable that the higher the resolution of the lithography device 110, the higher the cost of the lithography system, and the higher the precision of the structure that can be prepared by the lithography system. Therefore, suitable lithography systems may be selected according to the requirements of different application scenarios.

In the embodiments of the present disclosure, the ESD ring is arranged in the exposed area, and the feature size of the arranged ESD ring is less than the resolution of the lithography device. In this way, the ESD ring does not image when the lithography device exposes, thereby not influencing the formation of the device pattern projected onto the photoresist covering the semiconductor structure, and achieving the electrostatic protection of the device pattern in the exposed area.

The above description is only the specific implementation modes of the disclosure, but the protection scope of the disclosure is not limited thereto. Any change or replacement that those skilled in the art can easily conceive in the scope of technologies disclosed by the disclosure shall fall within the protection scope of the disclosure. Therefore, the scope of protection of the present disclosure shall be subject to the scope of protection of the claims.

1. A lithography system, comprising:
a lithography device; and
a mask adapted to the lithography device, the mask having an exposed area and a non-exposed area arranged around the exposed area;
wherein the mask comprises:
a device pattern, which is arranged in the exposed area and configured to be projected onto photoresist covering a semiconductor structure during exposure; and
an Electrostatic Discharge (ESD) ring, which is arranged in the exposed area and surrounds the device pattern; wherein the ESD ring has a feature size less than a resolution of the lithography device, and there is a preset spacing between the ESD ring and the device pattern.

2. The lithography system of claim 1, wherein,
the mask comprises a plurality of ESD rings arranged in parallel and surrounding the device pattern; wherein a minimum distance between adjacent two ESD rings is greater than or equal to the feature size of the ESD ring.

3. The lithography system of claim 2, wherein the minimum distance between the adjacent two ESD rings is equal to 1.5 to 2.5 times the feature size of the ESD ring.

4. The lithography system of claim 2, wherein the plurality of ESD rings are equally spaced apart.

5. The lithography system of claim 2, wherein the plurality of ESD rings have a same width.

6. The lithography system of claim 2, wherein centers of symmetry of the plurality of ESD rings overlap with each other.

7. The lithography system of claim 1, wherein the ESD ring has a rectangular, square or annular shape.

8. The lithography system of claim 1, wherein materials forming the ESD ring comprise quartz.

9. The lithography system of claim 1, wherein the mask further comprises:
an alignment mark, which is arranged in the non-exposed area and configured to align the mask with a light source of the lithography device.

10. The lithography system of claim 1, wherein the lithography device comprises: an I-Line lithography machine, a KrF lithography machine, an ArF dry lithography machine or ArF immersion lithography machine.

11. The lithography system of claim 10, wherein,
the lithography device is the I-Line lithography machine, and the feature size of the ESD ring is less than 1120 nm.

12. The lithography system of claim 10, wherein,
the lithography device is the KrF lithography machine, and the feature size of the ESD ring is less than 320 nm.

13. The lithography system of claim 10, wherein,
the lithography device is the ArF dry lithography machine, and the feature size of the ESD ring is less than 228 nm.

14. The lithography system of claim 10, wherein,
the lithography device is the ArF immersion lithography machine, and the feature size of the ESD ring is less than 152 nm.

15. The lithography system of claim 1, wherein,
the preset spacing is greater than 0.

16. The lithography system of claim 10, wherein,
the device pattern has a feature size greater than or equal to the resolution of the lithography device .
